(19) United States
(12) Patent Application Publication
(10) Pub. No.: US 2009/0135640 A1
(43) Pub. Date: May 28, 2009

(54) ELECTROMIGRATION-PROGRAMMABLE SEMICONDUCTOR DEVICE WITH BIDIRECTIONAL RESISTANCE CHANGE

(75) Inventors: Deok-Kee Kim, Bedford Hills, NY (US); Chuck Thuc Le, Poughkeepsie, NY (US); Byeongju Park, Plainview, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/946,450

(22) Filed: Nov. 28, 2007

(51) Int. Cl. G11C 17/16

(52) U.S. Cl. 365/96

(57) ABSTRACT

An electromigration-programmable semiconductor device may be programmed to increase the resistance or to decrease the resistance by selecting the amount of current passed through the electromigration-programmable semiconductor device. The electromigration-programmable semiconductor device comprises an anode, a cathode, and a link, each having a semiconductor portion and a metal semiconductor alloy portion. The metal semiconductor alloy portion of the link comprises two disjoined sub-portions with a gap therebetween. A low programming current fills the gap by electromigrating a small amount of metal semiconductor alloy from the cathode, A high programming current forms a large metal-semiconductor-alloy-deleted area in the cathode to increase the resistance. A tri-state programming is achieved by selecting the programming current level.

### RELATED APPLICATION

The present application is related to a co-pending U.S. patent application Ser. No. 11/683,068 filed on Mar. 7, 2007, which is incorporated herein by reference.

### FIELD OF THE INVENTION

The present invention relates to semiconductor memory devices, and particularly, to a semiconductor memory system comprising an electromigration-programmable semiconductor device and methods of manufacturing and operating the same.

### BACKGROUND OF THE INVENTION

Electrical antifuses and fuses employ electromigration of a metal semiconductor alloy to store non-erasable information. Once programmed, the programmed state of a fuse or an antifuse does not revert to the original state on its own; that is, the programmed state of the fuse or the antifuse is not reversible. For this reason, electrical fuses and antifuses are called One-Time-Programmable (OTP) memory elements. Thus, fuses and antifuses are conducive to the manufacture of a programmable read only memory (PROM). Programming or lack of programming constitutes one bit of stored information in a fuse or an antifuse. The difference between a fuse and an antifuse is the way the resistance of the memory element is changed during the programming process. A semiconductor fuse has a low initial resistance state that may be changed to a higher resistance state through programming, i.e., through electrical bias conditions applied to the fuse. In contrast, a semiconductor antifuse has a high initial resistance state that may be changed to a low resistance state through programming.

Various methods of implementing an antifuse in a semiconductor structure have been known in the prior art. In general, an antifuse includes one insulating layer sandwiched between two electrically conducting plates. In some cases, the insulating layer is a dielectric layer such as silicon dioxide or silicon nitride. In some other cases, the insulating layer comprises a stack of multiple layers including at least one silicon nitride layer and at least one silicon dioxide layer such as an oxide/nitride/oxide (ONO) stack. In a typical antifuse, the three components of the antifuse, i.e., the first electrically conducting plate, the insulating layer, and the second conducting plate, are built in a vertical stack. By supplying a large voltage difference across the two electrically conducting plates, a dielectric breakdown is induced and a current path between the two electrically conducting plates is formed, whereby the high resistance state of the antifuse changes to a low resistance state. Various materials may be used for each of the two electrically conducting plates. Improvements upon the basic structure are also known in the prior art. In one example, U.S. Pat. No. 6,853,049 utilizes a silicide for one electrically conducting plate and polysilicon for the other electrically conducting plate. In another example, U.S. Pat. No. 6,750,530 provides a mechanism for lowering.the antifuse programming voltage by providing a resistive heating element adjacent to, but not in contact with the antifuse.

Most electrical fuses and electrical antifuses known in the art store binary information. An unprogramed, or intact, electrical fuse or electrical antifuse represents one state, e.g., a state representing a “0” bit, while a programmed electrical fuse or electrical antifuse represents another state, e.g., a state representing a “1” bit. In the case of an electrical fuse, the programmed state has a higher resistance than the unprogrammed state, while in the case of an electrical antifuse, the programmed state has a lower resistance than the unprogrammed state.

Given that typical electrical fuses and electrical antifuses occupy a rather large per-bit area in a semiconductor device, efforts have been made to form electromigration-induced storage devices capable of storing more than a binary bit of information. U.S. Patent Application Publication No. 2007/0159231 to Lin et al. proposes an electrical fuse that is provided with two programming transistors of unequal sizes. By selecting a transistor to provide a programming current to a conventional electrical fuse having a contiguous metal semiconductor alloy material extending from an anode to a cathode, the resistance of the electrical fuse may be increased by a different amount. Thus, a ternary bit of information may be stored in this type of electrical fuse, A disadvantage of this approach is that each electrical fuse necessarily requires two programming transistors, which take up a large circuit area. Another disadvantage of this approach is that the change of resistance is always an increase, which requires that a sense circuit detect the degree of change in the resistance. Any offset introduced in a sense circuitry may produce erroneous readings since the sense circuit must ascertain the degree of increase in the resistance between a small increase in the resistance and a large increase in the resistance.

In view of the above, there exists a need for an electromigration based ternary bit memory that enables sensing of resistance changes less critically dependent on a sensing circuit, thus increasing reproducibility and reliability of sensing of ternary bit information.

Further, there exists a need for an electromigration based ternary bit memory that does not necessarily require multiple programming transistors, thus reducing the size of the overall electromigration memory circuit.

### SUMMARY OF THE INVENTION

The present invention addresses the needs described above by providing a “bidirectional electromigration memory” device, “bidirectional electromigration memory” circuits, and methods of manufacturing and operating such a device and circuits.

In the present invention, an electromigration-programmable semiconductor device may be programmed to increase the resistance or to decrease the resistance by selecting the amount of current passed through the electromigration-programmable semiconductor device. The electromigration-programmable semiconductor device comprises an anode, a cathode, and a link, each having a semiconductor portion and a metal semiconductor alloy portion. The metal semiconductor alloy portion of the link comprises two disjoined sub-portions with a gap therebetween. A low programming current fills the gap by electromigrating a small amount of metal semiconductor alloy from the cathode. A high programming current forms a large metal-semiconductor-alloy-deleted area in the cathode to increase the resistance. A tri-state programming is achieved by selecting the programming current level.

According to an aspect of the present invention, a semiconductor memory system comprising a programmable semiconductor device and a programming current supply circuit is provided. The programmable semiconductor device comprises:

an anode having an anode semiconductor portion and an anode metal semiconductor alloy portion;

a cathode having a cathode semiconductor portion and a cathode metal semiconductor alloy portion; and

a link having a link semiconductor portion, a first link metal semiconductor alloy portion, and a second link metal semiconductor alloy portion, wherein the link semiconductor portion laterally abuts the anode semiconductor portion and the cathode semiconductor portion and vertically abuts the first and second link metal semiconductor alloy portions, wherein the first link metal semiconductor alloy portion laterally abuts the cathode metal semiconductor alloy portion, wherein the second link metal semiconductor alloy portion laterally abuts the anode metal semiconductor alloy portion, and wherein the first link metal semiconductor alloy portion is disjoined from the second link metal semiconductor alloy portion.

The programming current supply circuit comprises a programming transistor electrically connected to the programmable semiconductor device in a serial connection, wherein the programming transistor provides two selectable levels of programming current by modulation of voltage on a gate of the programming transistor or by modulation of a voltage between a source and a drain of the programming transistor, and wherein one of the two levels of programming current increases a resistance of the programmable semiconductor device and another of the two levels of programming current decreases a resistance of the programmable semiconductor device.

According to another aspect of the present invention, a method of programming a programmable semiconductor device is provided. The programmable semiconductor device has a first resistance value and comprises:

an anode having an anode semiconductor portion and an anode metal semiconductor alloy portion;

a cathode having a cathode semiconductor portion and a cathode metal semiconductor alloy portion; and

a link having a link semiconductor portion, a first link metal semiconductor alloy portion, and a second link metal semiconductor alloy portion, wherein the link semiconductor portion laterally abuts the anode semiconductor portion and the cathode semiconductor portion and vertically abuts the first and second link metal semiconductor alloy portions, wherein the first link metal semiconductor alloy portion laterally abuts the cathode metal semiconductor alloy portion, wherein the second link metal semiconductor alloy portion laterally abuts the anode metal semiconductor alloy portion, and wherein the first link metal semiconductor alloy portion is disjoined from the second link metal semiconductor alloy portion,

The method comprises:

providing a programming transistor electrically connected to the programmable semiconductor device in a serial connection;

selecting a level of programming current to be supplied to the programmable semiconductor device by modulation of voltage on a gate of the programming transistor or by modulation of a voltage between a source and a drain of the programming transistor; and

passing a programming current pulse through the programmable semiconductor device, wherein a resistance of the programmable semiconductor device increases to a second resistance value or decreases to a third resistance value depending on the level of programming current, and wherein the first resistance value is less than the second resistance value and greater than the third resistance value.

### BRIEF DESCRIPTION OF THE DRAWING

FIGS. 1A-3D shows sequential views of an exemplary programmable semiconductor device, which is a “bidirectional electromigration memory” device. FIGS. 4A-4D show a programmed exemplary programmable semiconductor device with a low level of current so that the resistance of the exemplary programmable semiconductor device is decreased upon programming. FIGS. 5A-5D show a programmed exemplary programmable semiconductor device with a high level of current so that the resistance of the exemplary programmable semiconductor device is increased upon programming. Figures with the same numeral correspond to a same stage of a manufacturing process. Figures with the same alphabetical suffix are the same type of views. Specifically, figures with the suffix, “A” are top down views in which a middle-of-line dielectric layer 800 is omitted when applicable. Figures with the suffix, “B” are vertical cross-sectional views along the plane B-B′ of the figure with the same figure number and the suffix, “A.” Figures with the suffix, “C” are vertical cross-sectional views along the plane C-C′ of the figure with the same figure number and the suffix, “A.” Figures with the suffix, “D” are vertical cross-sectional views along the plane D-D′ of the figure with the same figure number and the suffix, “A.”

FIGS. 6A-6C are a first, a second, and a third exemplary semiconductor memory system according to a first, a second, and a third embodiment of the present invention.

FIGS. 7A-7C are top down scanning electron micrographs of an unprogrammed bidirectional electromigration memory device, a programmed bidirectional electromigration memory device having a lowered resistance, and a programmed bidirectional electromigration memory device having a raised resistance, respectively.

FIG. 8 is a graph showing distribution of resistance as a function of the voltage applied to the gate of a programming transistor for programmed bidirectional electromigration memory devices according to the first embodiment of the present invention.

### DETAILED DESCRIPTION OF THE INVENTION

As stated above, the present invention relates to a semiconductor memory system comprising an electromigration-programmable semiconductor device and methods of manufacturing and operating the same, which will now be described in greater detail by referring to the drawings.

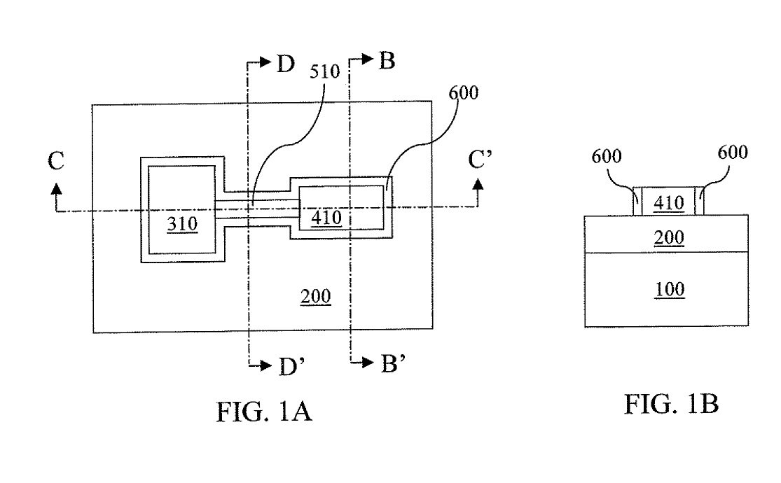

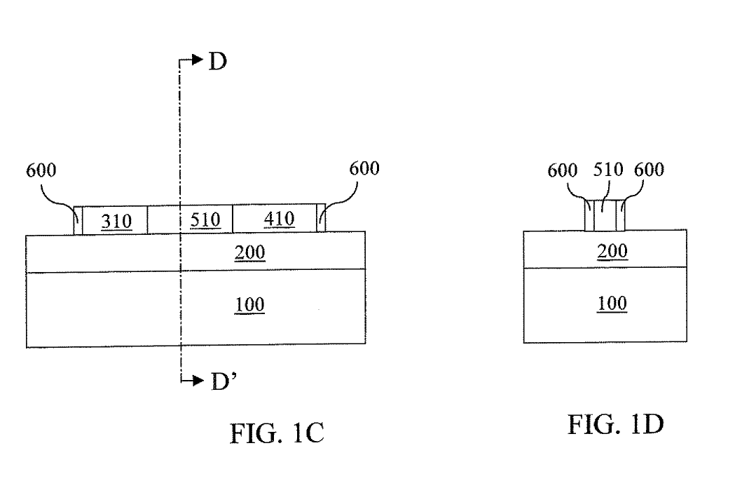

Referring to FIGS. 1A-1D, an exemplary programmable semiconductor device according to the present invention, shown at an early stage of manufacturing, comprises a substrate 100, an insulating layer 200, a cathode semiconductor portion 310, an anode semiconductor portion 410, a link semiconductor portion 510, and a dielectric spacer 600. The substrate 100 may be an insulator substrate, a metal substrate, or a semiconductor substrate, In case the substrate 100 is a semiconductor substrate, the substrate 100 may be a bulk semiconductor substrate, a semiconductor-on-insulator (SOI) substrate, or a hybrid substrate having a bulk portion and an SOI portion. The insulting layer 200 comprises an insulating material such as a dielectric oxide or a dielectric nitride. The insulating layer 200 may be a shallow trench isolation structure formed concurrently with other shallow trench isolation structures in typical semiconductor processing sequence.

The cathode semiconductor portion 310, the anode semiconductor portion 410, and the link semiconductor portion 510 are formed integrally, i.e., as one piece without any physical interface therebetween, by deposition of a semiconductor layer and lithographic patterning. The semiconductor layer comprises a semiconductor material such as silicon, a silicon germanium alloy, a silicon carbon alloy, a silicon carbon germanium alloy, GaAs, InAs, InP, other III-V compound semiconductors, or II-VI compound semiconductors. Each of the cathode semiconductor portion 310, the anode semiconductor portion 410, and the link semiconductor portion 510 may be p-doped or n-doped, i.e., may have more of p-type dopants than n-type dopants or vice versa. The dopant concentration may be in the range from about 1.0×10¹⁵ atoms/cm³ to about 1.0×10²¹ atoms/cm³. Alternately, the cathode semiconductor portion 310 and/or the anode semiconductor portion 410 may be undoped. The cathode semiconductor portion 310, the anode semiconductor portion 410, and the link semiconductor portion 510 may be formed concurrently with the formation of gate lines of a field effect transistor.

The cathode semiconductor portion 310 does not adjoin the anode semiconductor portion 410. The link semiconductor portion 510 laterally abuts the cathode semiconductor portion 310 on one end and the anode semiconductor portion 410 on another end. The thickness of the semiconductor layer, and consequently, the thickness of each of the cathode semiconductor portion 310, the anode semiconductor portion 410, and the link semiconductor portion 510 may be from about 50 nm to about 300 nm, and typically from about 80 nm to about 150 nm.

The dielectric spacer 600 may be optionally formed on the exemplary programmable semiconductor device by deposition of a dielectric layer followed by an anisotropic reactive ion etch. The dielectric spacer 600 comprises a dielectric material such as a dielectric oxide or a dielectric nitride. The dielectric spacer 600 is formed concurrently with formation of a gate spacer of a field effect transistor.

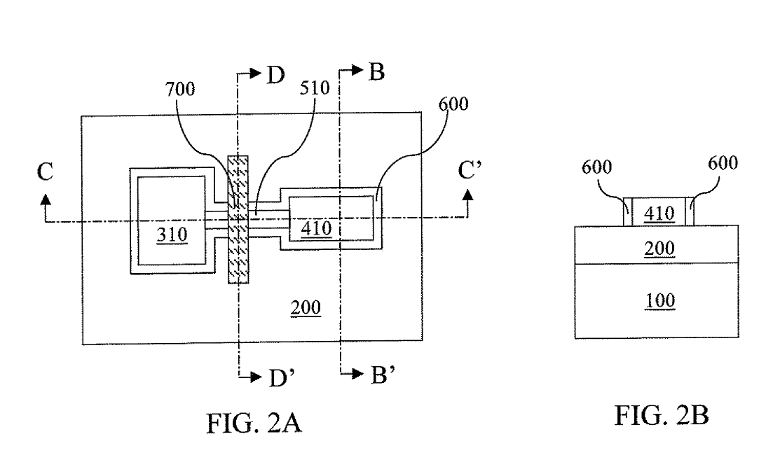

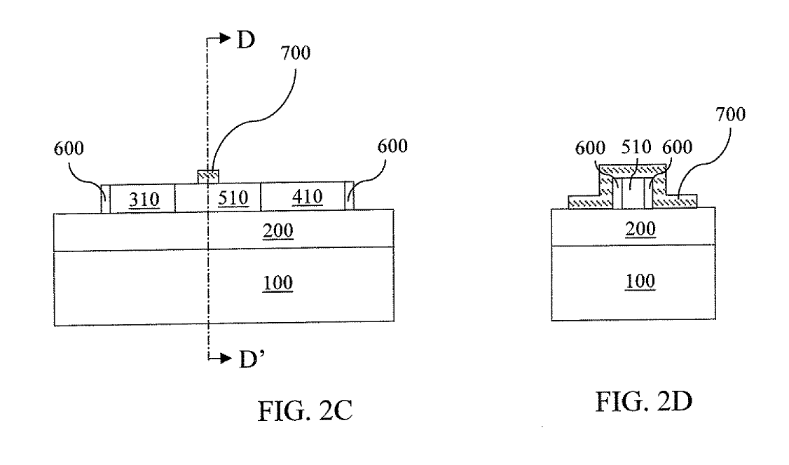

Referring to FIGS. 2A-2D, a dielectric masking structure 700 is formed over a region of the link semiconductor portion 510 by deposition of a dielectric masking layer (not shown) followed by lithographic patterning. Preferably, the link semiconductor portion 510 is exposed on both sides of the dielectric masking structure 700. Preferably, the width of the dielectric masking structure 700, which is the separation distance between the two exposed regions of the link semiconductor portion 510, is a lithographic critical dimension, i.e., a minimum lithographically printable dimension. For example, the width of the dielectric masking structure 700 may be from about 30 nm to about 240 nm, although lesser and greater widths are contemplated herein also.

The dielectric masking structure 700 comprises a dielectric material such as a dielectric oxide or a dielectric nitride. For example, the dielectric masking structure 700 may comprise silicon nitride. The thickness of the dielectric masking structure 700 may be from about 10 nm to about 300 nm, and typically from about 30 nm to about 100 nm, although lesser and greater thicknesses are contemplated herein also.

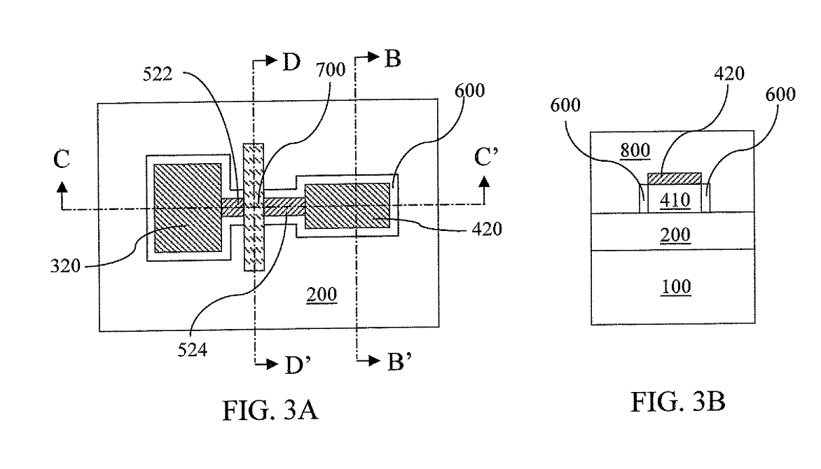

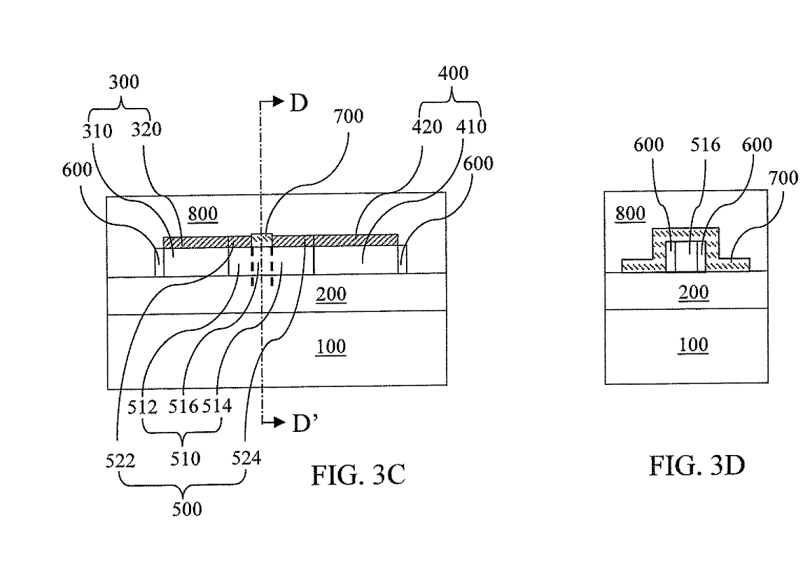

Referring to FIGS. 3A-3D, a metal layer (not shown) is deposited directly on the cathode semiconductor portion 310, the anode semiconductor portion 410, and exposed regions of the link semiconductor portion 510. The metal layer comprises a metal capable of forming a metal semiconductor alloy with the underlying semiconductor material. For example, the metal may be tungsten, tantalum, titanium, cobalt, nickel, platinum, osmium, another elemental metal, or an alloy thereof. A preferred thickness of the metal layer ranges from about 5 nm to about 50 nm, more preferably from about 10 nm to about 25 nm. The metal layer can be readily deposited by any suitable deposition technique, including, but not limited to: atomic layer deposition (ALD), chemical vapor deposition (CVD), and physical vapor deposition (PVD). Optionally, a metal nitride capping layer (not shown) may be deposited over the metal layer. The metal nitride capping layer may contain a refractory metal nitride such as TaN, TiN, WN, OsN and has a thickness ranging from about 5 nm to about 50 nm, and preferably from about 10 nm to about 30 nm.

The exemplary programmable semiconductor device is thereafter annealed at a pre-determined elevated temperature at which the metal layer reacts with the semiconductor material of the cathode semiconductor portion 310, the anode semiconductor portion 410, and exposed regions of the link semiconductor portion 510 to form various metal semiconductor alloy portions in a metallization process. The annealing is typically performed in an inert gas atmosphere, e.g., He, Ar, N₂, or forming gas, at a temperature that is conducive to formation of the metal semiconductor alloy. The metal semiconductor alloy may be formed in multiple stages to induce formation of different phases of the metal semiconductor alloy so that the resulting metal semiconductor alloy has a low resistivity. The temperature for formation of the metal semiconductor alloy ranges from about 100° C. to about 800° C., typically from about 300° C. to about 700° C., and most typically from about 300° C. to about 600° C. A continuous heating at a constant temperature or various ramping in temperature may be employed. In case the semiconductor material comprises silicon, the metal semiconductor alloy is a metal silicide.

During the metallization process, an upper region of the cathode semiconductor portion 310 reacts with the metal layer and forms a cathode metal semiconductor alloy portion 320, an upper region of the anode semiconductor portion 410 reacts with the metal layer and forms an anode metal semiconductor alloy portion 320, a first exposed region of the link semiconductor portion 510 to one side of the dielectric masking structure 700 reacts with the metal layer and forms a first link metal semiconductor alloy portion 522, and a second exposed portion of the link semiconductor portion 510 to the other side of the dielectric masking structure 700 reacts with the metal layer and forms a second link metal semiconductor alloy portion 524.

The region of the link semiconductor portion 510 that is located directly beneath the first link metal semiconductor alloy portion 522 is herein referred to as a first link semiconductor sub-portion 512. The region of the link semiconductor portion 510 that is located directly beneath the second link metal semiconductor alloy portion 524 is herein referred to as a second link semiconductor sub-portion 514. The region of the link semiconductor portion 510 that is located directly beneath the dielectric masking structure 700 is herein referred to as a third link semiconductor sub-portion 516. The boundary between the third link semiconductor sub-portion 512 and the first link semiconductor sub-portion 512 or the second link semiconductor sub-portion 524 vertically coincides with the edge of the dielectric masking structure 700. The first, second, and third link semiconductor sub-portions (512, 514, 516) collectively constitute the link semiconductor region 510.

The cathode semiconductor portion 310 and the cathode metal semiconductor alloy portion 320 collectively constitute a cathode 300. The anode semiconductor portion 410 and the anode metal semiconductor alloy portion 420 collectively constitute an anode 400. The link semiconductor region 510, the first link metal semiconductor alloy portion 522, and the second link metal semiconductor alloy portion 524 collectively constitute a link 600. The resistance between the anode 400 and the cathode 300, which is herein referred to as a first resistance value, is significantly affected by the break in the metal semiconductor alloy in the link 500, i.e., by the gap between the first link metal semiconductor alloy portion 522 and the second link metal semiconductor alloy portion 524 since the resistivity of any semiconductor material, even in the most heavily doped state, is at least an order of magnitude higher that the resistivity of any metal semiconductor alloy material. The difference in the resistivity may be several orders of magnitude in some cases.

Preferably, the doping of the link semiconductor portion 510 is controlled such that the first resistance value is low enough to allow a sufficient level of programming current during a weak programming or a strong programming of the exemplary programmable semiconductor device as will be described below. A typical range for the first resistance value may be from about 1 kΩ to about 20 kΩ.

A middle-of-line (MOL) dielectric layer 800 is formed on the exemplary programmable semiconductor device. The MOL dielectric layer 800 vertically abuts top surfaces of the cathode metal semiconductor alloy portion 320, the anode metal semiconductor alloy portion 420, the first link metal semiconductor alloy portion 522, the second link metal semiconductor alloy portion 524, the dielectric masking structure 700, and the insulating layer 200. The MOL dielectric layer 800 may comprise a silicon oxide, a silicon nitride, a chemical vapor deposition (CVD) low-k dielectric material, or a spin-on low-k dielectric material.

Non-limiting examples of the silicon oxide include undoped silicate glass (USG), borosilicate glass (BSG), phosphosilicate glass (PSG), borophosphosilicate glass (BPSG), fluorosilicate glass (FSG), and TEOS (tetra-ethyl-ortho-silicate) oxide. The silicon nitride may be a stoichiometric nitride, or a non stoichiometric nitride applying a tensile or compressive stress to underlying structures.

Contact via holes (not shown) are formed in the MOL dielectric layer 800 and filled with metal to form various metal contacts. Specifically, at least one cathode contact via (not shown) vertically abutting the cathode metal semiconductor alloy portion 320 and at least one anode contact via (not shown) vertically abutting the anode metal semiconductor alloy portion 420 are formed.

Referring to FIGS. 4A-4C, a “weakly programmed” exemplary programmable semiconductor device is formed by a “weak” programming of the exemplary programmable semiconductor device. The weak programming of the exemplary programmable semiconductor device is effected by flowing a limited amount of current from the anode 400 to the cathode 300 of the exemplary programmable semiconductor device shown in FIGS. 3A-3D such that a small region of the cathode metal semiconductor alloy portion 320 abutting the first link metal semiconductor alloy portion 522 is electromigrated into the link 500. Thus, the structure of the cathode 300 and the link 500 are changed. The changed structure of the cathode 300 through the weak programming is herein referred to as a “weakly programmed cathode” 350, and the changed structure of the link 500 through the weak programming is herein referred to as a “weakly programmed link” 550.

The amount of the metal semiconductor alloy material electromigrated from the cathode metal semiconductor alloy portion 320 to the weakly programmed link 550 is controlled by the magnitude of current that flows between the anode 400 and the cathode 300 during the weak programming of the exemplary programmable semiconductor device. The amount of current to cause a weak programming of the exemplary programmable semiconductor device is determined primarily by the width of the dielectric masking structure 700, the dimensions of the link 500, and the composition of the link 500. For example, in case the width, measured in the direction of the programming current over the link 500, i.e., measured in the direction of the C-C′ plane in FIG. 3A, of the dielectric masking structure 700 is about 240 nm, and the link 500 has a rectangular horizontal cross-sectional area having a length, measured in the direction of the programming current in the link 500, of about 400 nm and a width, measured in the direction perpendicular to the programming current in the link 500, i.e., measured in the direction of the plane D-D′ in FIG. 3A, of about 63 nm, the range of current that induces the weak programming may be from about 1 mA to about 4 mA for the case of nickel silicide as the metal semiconductor alloy. As the width of the dielectric masking structure 700 shrinks, and as the width of the link 500 shrinks, the weak current that induces the weak programming is reduced.

The post-weak programming cathode metal semiconductor alloy portion 320′ is disjoined from the weakly programmed link 550. The anode semiconductor portion 310 of the weakly programmed cathode 350 comprises a first anode semiconductor portion 312 located directly underneath the post-weak programming cathode metal semiconductor alloy portion 320′ and a second anode semiconductor portion 314 that is not covered by any metal semiconductor alloy.

The weakly programmed link 550 comprises a weakly electromigrated metal semiconductor alloy portion 540 and a weakly programmed link semiconductor portion 530. The volume of the weakly programmed link semiconductor portion 530 is less than the volume of the link semiconductor alloy 510 (See FIGS. 3A-3D) prior to programming. The weakly electromigrated metal semiconductor alloy portion 540 extending from the anode 400 to the weakly programmed anode 350 provides a low resistance current path through the weakly programmed link 550 such that the resistance between the anode 400 and the weakly programmed cathode 350, which is herein referred to as a second resistance value, is lower than the first resistance value, i.e., the resistance between the anode 400 and the cathode 300 (See FIGS. 3A-3D) prior to the weak programming.

Referring to FIGS. 5A-5D, a “strongly programmed” exemplary programmable semiconductor device is formed by a “strong” programming of the exemplary programmable semiconductor device. The strong programming of the exemplary programmable semiconductor device is effected by flowing a sufficient amount of current from the anode 400 to the cathode 300 of the exemplary programmable semiconductor device shown in FIGS. 3A-3D such that a large region of the cathode metal semiconductor alloy portion 320 abutting the first link metal semiconductor alloy portion 522 is electromigrated into the link 500. Thus, the structure of the cathode 300 and the link 500 are changed. The changed structure of the cathode 300 through the strong programming is herein referred to as a “strongly programmed cathode” 360, and the changed structure of the link 500 through the strong programming is herein referred to as a “strongly programmed link” 560.

The amount of current to cause a strong programming of the exemplary programmable semiconductor device is determined primarily by the width of the dielectric masking structure 700, the dimensions of the link 500, and the composition of the link 500. For example, in case the width, measured in the direction of the programming current over the link 500, i.e., measured in the direction of the C-C′ plane in FIG. 3A, of the dielectric masking structure 700 is about 240 nm, and the link 500 has a rectangular horizontal cross-sectional area having a length, measured in the direction of the programming current in the link 500, of about 400 nm and a width, measured in the direction perpendicular to the programming current in the link 500, i.e., measured in the direction of the plane D-D′ in FIG. 3A, of about 63 nm, the range of current that induces the strong programming may be from about 5 mA to about 12 mA for the case of nickel silicide as the metal semiconductor alloy. As the width of the dielectric masking structure 700 shrinks, and as the width of the link 500 shrinks, the strong current that induces the strong programming is reduced.

The post-strong programming cathode metal semiconductor alloy portion 320″ is disjoined from the strongly programmed link 560. The anode semiconductor portion 310 of the strongly programmed cathode 360 comprises a first anode semiconductor portion 312 located directly underneath the post-strong programming cathode metal semiconductor alloy portion 320″ and a second anode semiconductor portion 314 that is not covered by any metal semiconductor alloy.

The strongly programmed link 560 comprises a strongly electromigrated metal semiconductor alloy portion 540′ and a strongly programmed link semiconductor portion 530′. The volume of the strongly programmed link semiconductor portion 530′ is less than the volume of the link semiconductor alloy 510 (See FIGS. 3A-3D) prior to programming. The strongly electromigrated metal semiconductor alloy portion 540′ abuts the post-electromigration anode 400′ but does not extend to the strongly programmed cathode 360. Instead, the strongly programmed link semiconductor portion 530′ laterally abuts the strongly programmed cathode 360 and the strongly electromigrated metal semiconductor alloy portion 540′ . Very often, dopants are depleted in the strongly programmed link semiconductor portion 530′ , rendering the resistivity of the strongly programmed link semiconductor portion 530′ several orders high in magnitude than the resistivity of the metal semiconductor alloy material comprising the strongly electromigrated metal semiconductor alloy portion 540′. Thus, the resistance of the strongly programmed link 560 is several orders of magnitude higher than the resistance of the link 500 prior to the strong programming. The resistance of the strongly programmed exemplary programmable semiconductor device, as measured between the post-electromigration anode 400′ and the strongly programmed cathode 360 and herein referred to as a third resistance value, is several orders of magnitude greater than the resistance of the exemplary programmable semiconductor device, i.e., the first resistance value.

Some electromigrated metal semiconductor alloy material may be electromigrated into the post-electromigration anode 400′, which comprises not only the anode semiconductor portion 410 and the anode metal semiconductor alloy portion 420 but also an electromigrated anode metal semiconductor alloy portion 440, which comprises an electromigrated metal semiconductor alloy material that is transported into the post-electromigration anode 400′ during the strong programming.

Thus, the exemplary programmable semiconductor device of the present invention is capable of achieving three distinct states including an unprogrammed state having the first resistance value, a weakly programmed state having the second resistance value, and a strongly programmed state having the third resistance value.

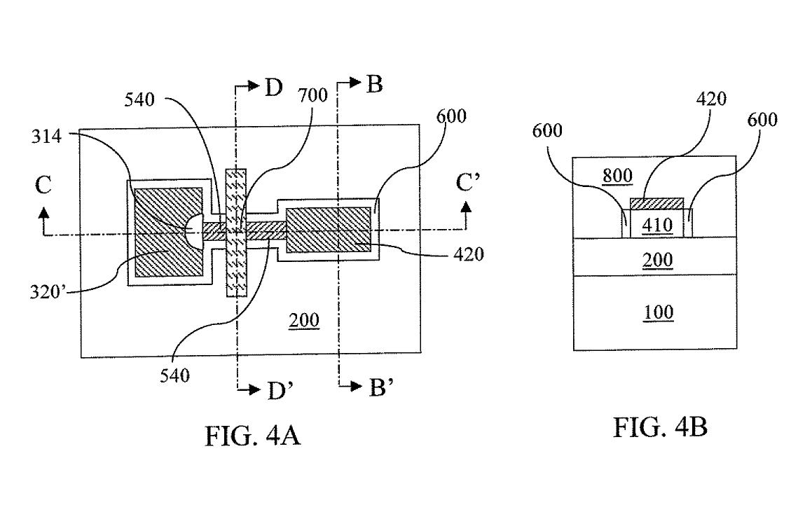

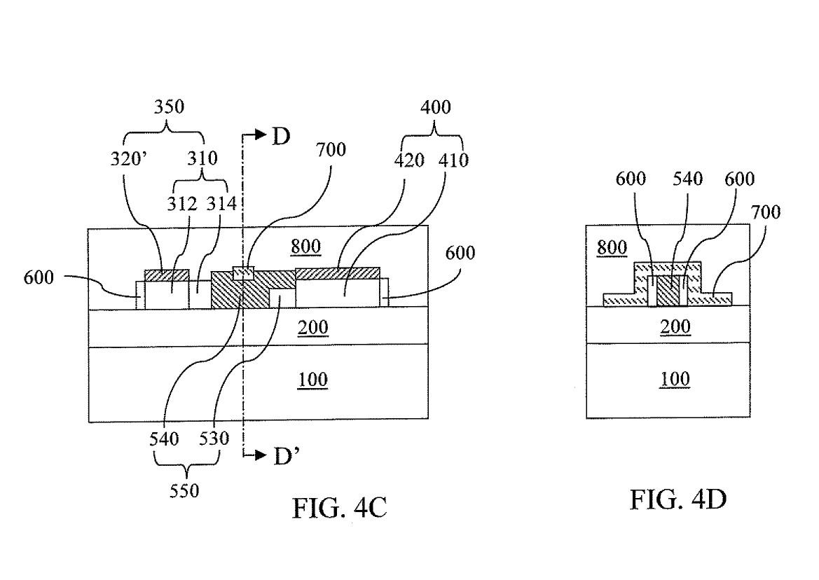

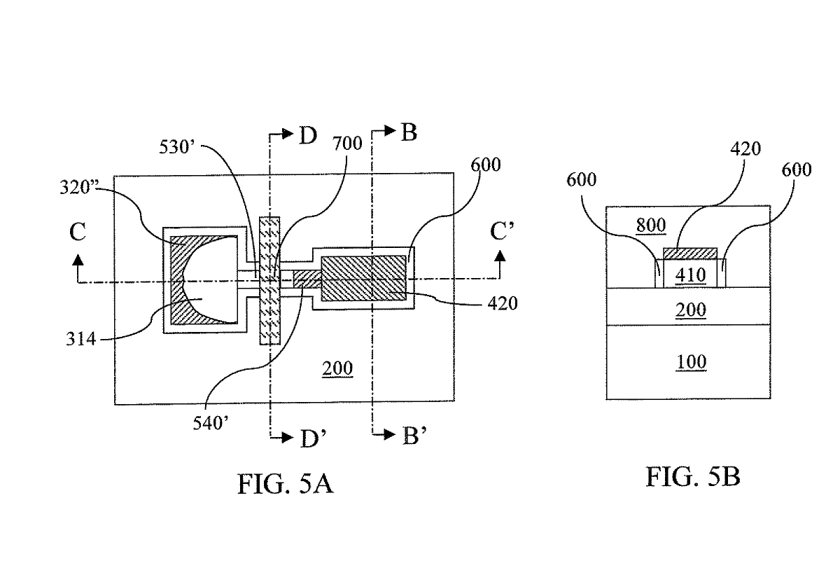

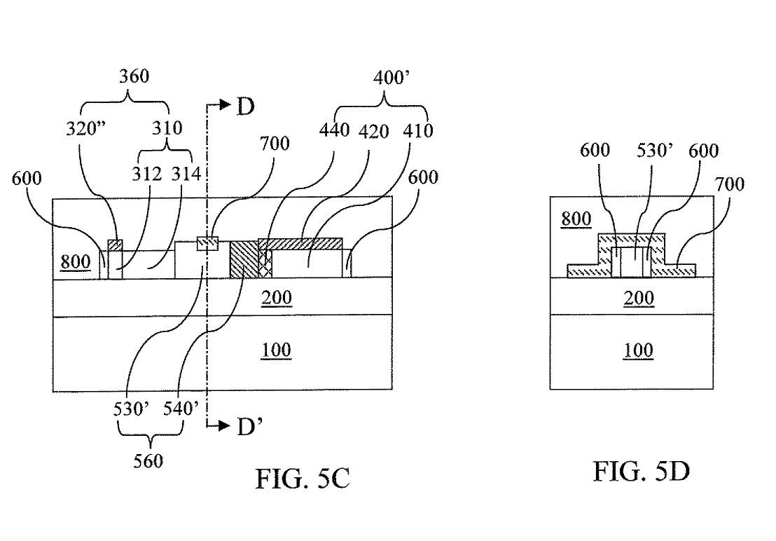

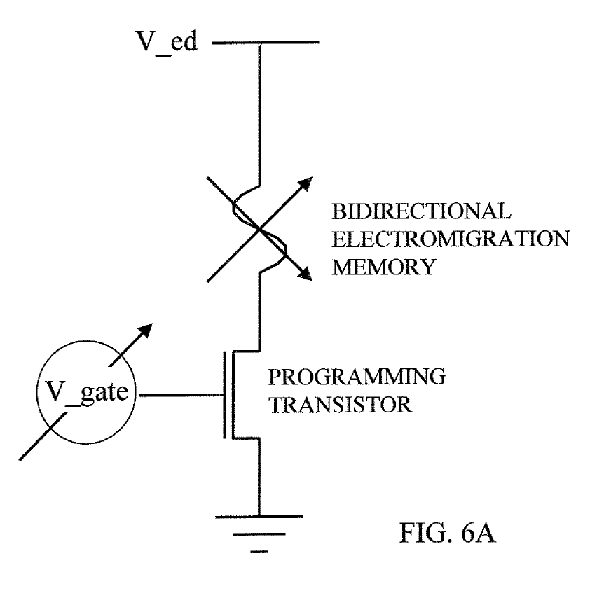

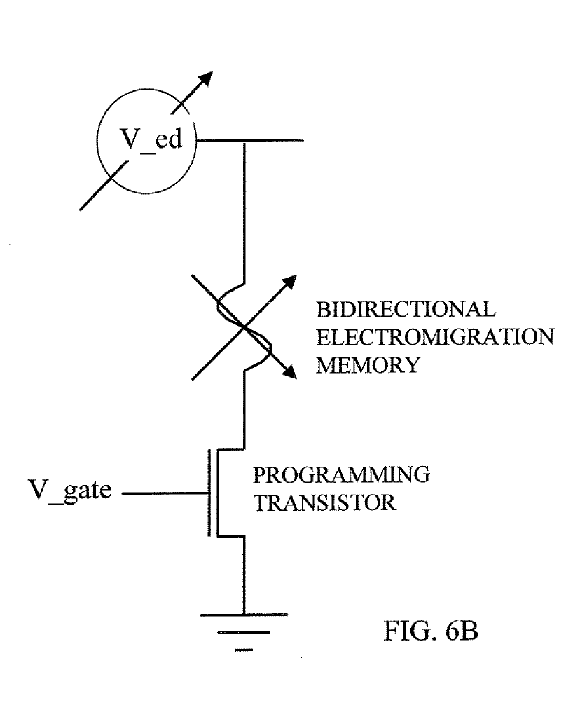

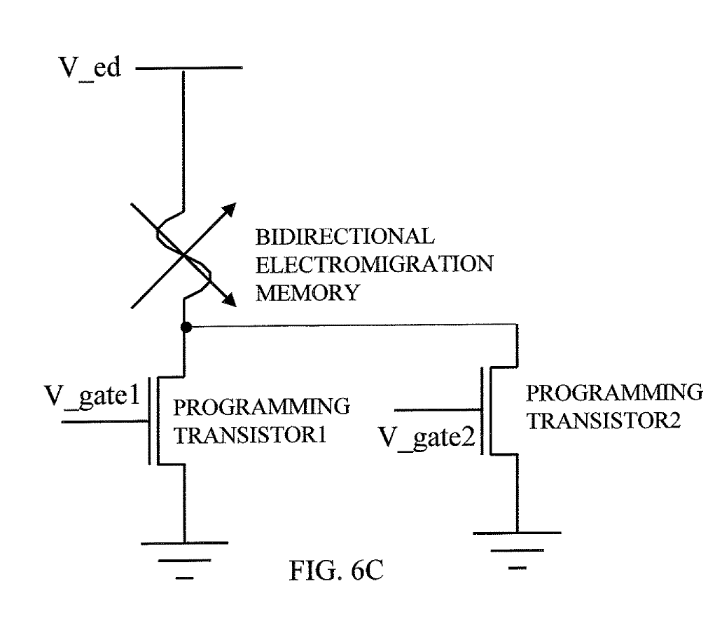

Referring to FIG. 6A, a first exemplary semiconductor memory system, comprising the exemplary programmable semiconductor device as described above and a programming current supply circuit, is provided according to a first embodiment of the present invention. The exemplary programmable semiconductor device is represented by a symbol for a bidirectional electromigration memory which has two criss-crossing arrows that represent that the resistance may be increased or decreased. The programming transistor is serially connected to the bidirectional electromigration memory to control the current through the bidirectional electromigration memory. Normally, the current through the programming transistor is zero. Prior to programming of the bidirectional electromigration memory, the bidirectional electromigration memory has a first resistance value, which is the same as the first resistance value of the unprogrammed exemplary programmable semiconductor device of FIGS. 3A-3D.

A constant voltage, which is herein referred to electromigration drive voltage V_ed, is supplied to the one side of the bidirectional electromigration memory. In case the electromigration drive voltage is positive, the anode of the exemplary programmable semiconductor device in FIGS. 3A-3D is connected to the electromigration drive voltage V_ed, while the cathode of the exemplary programmable semiconductor device is connected to the programming transistor. In case the electromigration drive voltage is negative, the cathode of the exemplary programmable semiconductor device in FIGS. 3A-3D is connected to the electromigration drive voltage V_ed, while the anode of the exemplary programmable semiconductor device is connected to the programming transistor.

A variable voltage supply is connected to the gate of the programming transistor to supply a gate voltage V_gate to the gate of the programming transistor. The gate voltage has two settings, a weak programming setting and a strong programming setting. The weak programming setting allows a low level of programming current to flow through the bidirectional electromigration memory to enable the weak programming of the exemplary programmable semiconductor device, i.e., the bidirectional electromigration memory, as shown in FIGS. 4A-4D. In this case, the resistance of the bidirectional electromigration memory changes to a second resistance value, which is the same as the second resistance value of the weakly programmed exemplary programmable semiconductor device of FIGS. 4A-4D. Since the second resistance value is less than the first resistance value, the resistance of the exemplary programmable semiconductor device decreases upon programming.

The strong programming setting allows a high level of programming current to flow through the bidirectional electromigration memory to enable the strong programming of the exemplary programmable semiconductor device, i.e., the bidirectional electromigration memory, as shown in FIGS. 5A-5D. In this case, the resistance of the bidirectional electromigration memory changes to a third resistance value, which is the same as the third resistance value of the strongly programmed exemplary programmable semiconductor device of FIGS. 5A-5D. Since the third resistance value is less than the first resistance value, the resistance of the exemplary programmable semiconductor device increases upon programming.

Referring to FIG. 6B, a second exemplary semiconductor memory system, comprising the exemplary programmable semiconductor device as described above and another programming current supply circuit, is provided according to a second embodiment of the present invention. The programming transistor is serially connected to the bidirectional electromigration memory to control the current through the bidirectional electromigration memory as in the first embodiment. Instead of a variable voltage supply connected to the gate of the programming transistor, the gate voltage setting for programming mode operation of the programming transistor is fixed.

However, a variable voltage supply is connected to the electromigration drive voltage V_ed. The electromigration drive voltage V_ed has two settings, a weak programming setting and a strong programming setting. The weak programming setting allows a low level of programming current to flow through the bidirectional electromigration memory to enable the weak programming of the exemplary programmable semiconductor device, while the strong programming setting allows a high level of programming current to flow through the bidirectional electromigration memory to enable the strong programming of the exemplary programmable semiconductor device.

As in the first embodiment, the exemplary programmable semiconductor device has the first resistance value prior to programming, and may have the second resistance value or the third resistance value after programming depending on whether a weak programming or a strong programming is selected. Thus, a tri state memory, or a ternary bit memory is achieved with the second exemplary semiconductor memory system as well.

Referring to FIG. 6C, a third exemplary semiconductor memory system, comprising the exemplary programmable semiconductor device as described above and yet another programming current supply circuit, is provided according to a third embodiment of the present invention. The programming current supply circuit comprises two programming transistors, i.e., “programming transistor1” and “programming transistor2.” The two programming transistors, as a set, are serially connected to the bidirectional electromigration memory to control the current through the bidirectional electromigration memory as in the first embodiment. The electromigration drive voltage V_ed is set at a constant value.

The two programming transistors are operated supply different amounts of current to the bidirectional electromigration memory. In one case, one of the two programming transistors may be turned on to provide a programming current for a weak programming of the bidirectional electromigration memory, or another of the two programming transistors may be turned on to provide a programming current for a strong programming of the bidirectional electromigration memory. Alternately, one of the two programming transistors may be turned on to provide a programming current for a weak programming of the bidirectional electromigration memory, or both of the two programming transistors may be turned on to provide a programming current for a strong programming of the bidirectional electromigration memory.

By optimizing the size of the two transistors and by manipulating the first gate voltage, “V_gate1 ” and the second gate voltage “V_gate2,” a weak programming or a strong programming may be performed on the exemplary programmable semiconductor device. The weak programming setting allows a low level of programming current to flow through the bidirectional electromigration memory to enable the weak programming of the exemplary programmable semiconductor device, while the strong programming setting allows a high level of programming current to flow through the bidirectional electromigration memory to enable the strong programming of the exemplary programmable semiconductor device.

As in the first embodiment, the exemplary programmable semiconductor device has the first resistance value prior to programming, and may have the second resistance value or the third resistance value after programming depending on whether a weak programming or a strong programming is selected. Thus, a tri state memory, or a ternary bit memory is achieved with the third exemplary semiconductor memory system as well.

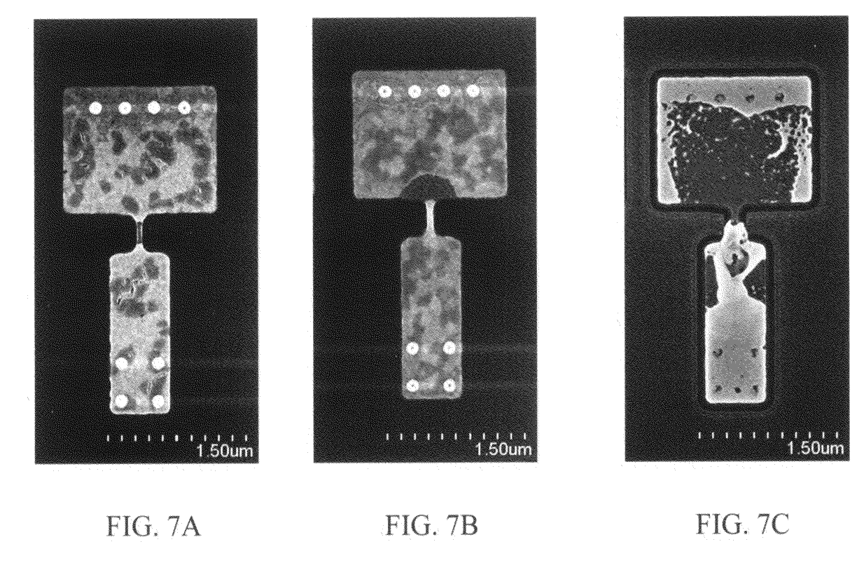

Referring to FIG. 7A, a top down scanning electron micrograph (SEM) picture of a physical implementation of the exemplary programmable semiconductor device according to the present invention is shown prior to programming. In this case, the metal semiconductor alloy is nickel silicide and the various semiconductor portions comprise p-doped silicon. A break, or a gap, in the metal semiconductor alloy is apparent in the link.

Referring to FIG. 7B, a top down scanning electron micrograph (SEM) picture of a physical implementation of the exemplary programmable semiconductor device according to the present invention is shown after a weak programming that reduced the resistance of the structure. A small silicide depleted region in the shape of a semicircle is shown in the cathode located above the link. The link comprises a contiguous nickel silicide that extends from the cathode to the anode. The presence of the contiguous nickel silicide that extends from the cathode to the anode, along with the presence of a relatively high level of doping, i.e., above 1.0×10²⁰/cm³ in atomic concentration, in the small silicide depleted region of the cathode semiconductor portion induces the reduction of the resistance upon the weak programming.

Referring to FIG. 7C, a top down scanning electron micrograph (SEM) picture of a physical implementation of the exemplary programmable semiconductor device according to the present invention is shown after a strong programming that increased the resistance of the structure. A large silicide depleted region is shown in the cathode located above the link. The link comprises a semiconductor portion that abuts the cathode and a nickel silicide portion that abuts the anode. The nickel silicide in the link does not extend to the cathode. The large nickel silicide depleted area in the cathode, as well as depletion of dopants in the cathode due to the high current employed in the strong programming, increases the resistance of the structure.

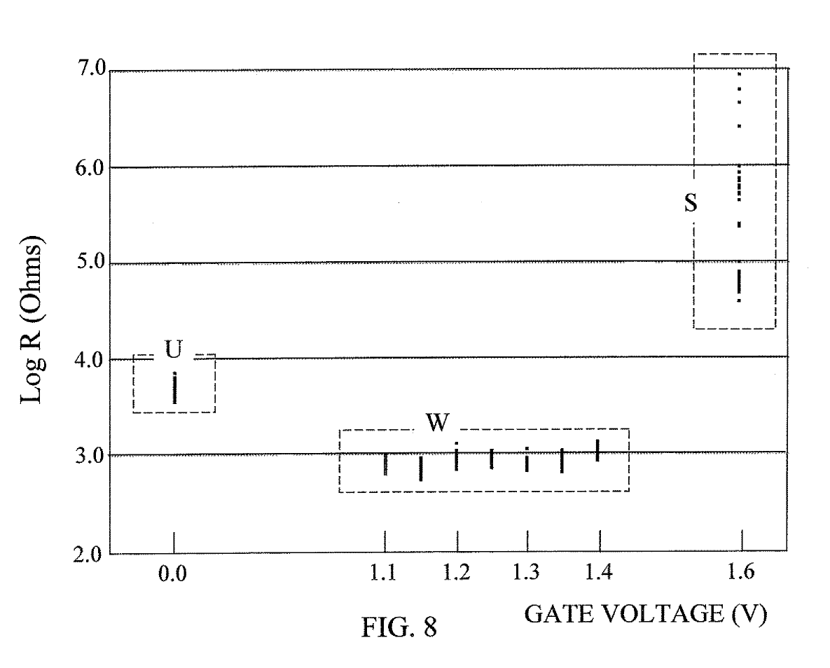

Referring to FIG. 8, resistance distributions of the exemplary programmable semiconductor device as implemented by the physical structures shown in FIGS. 7A-7C are shown in a logarithmic scale with a base of 10 as a function of the gate voltage according to the first embodiment of the present invention. The first resistance value, while conveniently referred to as a value in the description of the present invention, has a distribution shown in the box labeled “U,” which encloses the distribution of unprogrammed exemplary programmable semiconductor devices. The second resistance value likewise has a distribution shown in the box labeled “W,” which encloses the distribution of weakly programmed exemplary programmable semiconductor devices. The third resistance value likewise has a distribution shown in the box labeled “S,” which encloses the distribution of strongly programmed exemplary programmable semiconductor devices.

The distribution of the three resistance values do not vertically overlap, which implies that a reliable sensing circuit may be employed to detect the state of the exemplary programmable semiconductor device that is programmed employing any the three exemplary semiconductor memory systems. Thus, by selecting the mode of programming and selecting the level of current to flow through the exemplary programmable semiconductor device, a tri state data, or a ternary bit data may be encoded into the exemplary programmable semiconductor device. The data may be reliably sensed by employing a sense circuit that measures the resistance of the exemplary programmable semiconductor device by methods known in the art.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor memory system comprising a programmable semiconductor device and a programming current supply circuit,
wherein said programmable semiconductor device comprises:
an anode having an anode semiconductor portion and an anode metal semiconductor alloy portion;
a cathode having a cathode semiconductor portion and a cathode metal semiconductor alloy portion; and
a link having a link semiconductor portion, a first link metal semiconductor alloy portion, and a second link metal semiconductor alloy portion, wherein said link semiconductor portion laterally abuts said anode semiconductor portion and said cathode semiconductor portion and vertically abuts said first and second link metal semiconductor alloy portions, wherein said first link metal semiconductor alloy portion laterally abuts said cathode metal semiconductor alloy portion, wherein said second link metal semiconductor alloy portion laterally abuts said anode metal semiconductor alloy portion, and wherein said first link metal semiconductor alloy portion is disjoined from said second link metal semiconductor alloy portion,
and wherein said programming current supply circuit comprises a programming transistor electrically connected to said programmable semiconductor device in a serial connection, wherein said programming transistor provides two selectable levels of programming current by modulation of voltage on a gate of said programming transistor or by modulation of a voltage between a source and a drain of said programming transistor, and wherein one of said two levels of programming current increases a resistance of said programmable semiconductor device and another of said two levels of programming current decreases a resistance of said programmable semiconductor device.

2. A method of programming a programmable semiconductor device,
wherein said programmable semiconductor device has a first resistance value and comprises:
an anode having an anode semiconductor portion and an anode metal semiconductor alloy portion;
a cathode having a cathode semiconductor portion and a cathode metal semiconductor alloy portion; and
a link having a link semiconductor portion, a first link metal semiconductor alloy portion, and a second link metal semiconductor alloy portion, wherein said link semiconductor portion laterally abuts said anode semiconductor portion and said cathode semiconductor portion and vertically abuts said first and second link metal semiconductor alloy portions, wherein said first link metal semiconductor alloy portion laterally abuts said cathode metal semiconductor alloy portion, wherein said second link metal semiconductor alloy portion laterally abuts said anode metal semiconductor alloy portion, and wherein said first link metal semiconductor alloy portion is disjoined from said second link metal semiconductor alloy portion,
and wherein said method comprises:
providing a programming transistor electrically connected to said programmable semiconductor device in a serial connection;
selecting a level of programming current to be supplied to said programmable semiconductor device by modulation of voltage on a gate of said programming transistor or by modulation of a voltage between a source and a drain of said programming transistor; and
passing a programming current pulse through said programmable semiconductor device, wherein a resistance of said programmable semiconductor device increases to a second resistance value or decreases to a third resistance value depending on said level of programming current, and wherein said first resistance value is less than said second resistance value and greater than said third resistance value
